(19) United States
(12) Patent Application Publication
(10) Pub. No.: US 2026/0143666 A1
(43) Pub. Date: May 21, 2026

(54) SEMICONDUCTOR STRUCTURE AND METHODS OF FORMING THE SAME

(71) Applicant: TAIWAN SEMICONDUCTOR MANUFACTURING COMPANY, LTD., Hsinchu (TW)

(72) Inventors: Shih-Hao LIN, Hsinchu (TW); Jui-Lin CHEN, Taipei (TW); Yu-Bey WU, Hsinchu (TW); Ping-Wei WANG, Hsinchu (TW)

(21) Appl. No.: 19/093,691

(22) Filed: Mar. 28, 2025

Related U.S. Application Data
(60) Provisional application No. 63/723,147, filed on Nov. 21, 2024.

(51) Int. Cl. H10B 10/00; H10D 30/00; H10D 30/01; H10D 30/43; H10D 62/10; H10D 62/13; H10D 62/60; H10D 62/834; H10D 64/23; H10D 64/27

(52) U.S. Cl. CPC H10B 10/18; H10B 10/12; H10D 30/014; H10D 30/019; H10D 30/43; H10D 30/503; H10D 62/121; H10D 62/151; H10D 62/60; H10D 62/834; H10D 64/256; H10D 64/516

(57) ABSTRACT

Embodiments of the present disclosure provide a semiconductor device structure and methods of forming the same. In some embodiments, an implantation process is performed to implant a dopant into a S/D region to improve device performance. For example, source/drain regions of the transistors in a SRAM cell may be enhanced by additional dopants to improve the SRAM cell performance.

### CROSS-REFERENCE TO RELATED APPLICATIONS

This application claims priority to the U.S. Provisional Patent Application Ser. No. 63/723,147 filed Nov. 21, 2024, which is incorporated by reference in its entirety.

### BACKGROUND

Conventionally, integrated circuits (IC) are built in a stacked-up fashion, having transistors at the lowest level and interconnect, such as vias and lines, on top of the transistors to provide connectivity to the transistors. Power rails, for example metal lines for voltage sources and ground planes, are also above the transistors and may be part of the interconnect. As the integrated circuits continue to scale down, so do the power rails. Scaling down of power rails inevitably leads to increased voltage drop across the power rails, as well as increased power consumption of the integrated circuits.

### BRIEF DESCRIPTION OF THE DRAWINGS

Aspects of the present disclosure are understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a circuit diagram of a six transistor (6T) static random-access memory (SRAM) cell according to embodiments of the present disclosure.

FIGS. 1B and 1C are schematic top views of a SRAM cell structure according to embodiments of the present disclosure.

FIGS. 1D, 1E, 1F are schematic cross sectional views of a SRAM cell according to embodiments of the present disclosure.

FIG. 1G is a schematic cross sectional view of a SRAM cell according to another embodiment of the present disclosure.

FIG. 2 is a flow chart of a method of forming a semiconductor device according to embodiments of the present disclosure.

FIGS. 3A, 3B, 3C, 3D, 3E, 4, 5A, 5B, 5C, 5D, 6A, 6B, 6C, 6D, 7A, 7B, 7C, 7D, 8A, and 8B schematically illustrate various stages of manufacturing a semiconductor device structure according to embodiments of the present disclosure.

FIGS. 9A, 9B, 10A, 10B, 11A, and 11B schematically illustrate various stage of manufacturing a semiconductor device structure according to embodiments of the present disclosure.

FIGS. 12A and 12B schematically illustrate a semiconductor device structure according to embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “top,” “upper” and the like, may be used herein for ease of description to describe one element or feature's relationship to another element(s) or feature(s) as illustrated in the figures. The spatially relative terms are intended to encompass different orientations of the semiconductor device in use or operation in addition to the orientation depicted in the figures. The apparatus may be otherwise oriented (rotated 90 degrees or at other orientations) and the spatially relative descriptors used herein may likewise be interpreted accordingly.

Various embodiments to be described below relate generally to implanting a dopant of V group elements, such as phosphorus and arsenic, into an source/drain region of n-type metal-oxide semiconductor (NMOS) of a static random-access memory (SRAM) to achieve tunable SRAM Beta ratio, to improve SRAM Vmax and Vccmin, to bosset SRAM Icell performance, and to reduce current crowding. The implantation of the V group elements is applied to the source/drain region that is connected to a ground potential (Vss) of a pulldown (PD) transistor in a SRAM cell. In some embodiments, the ground potential Vss is connected from a backside of the substrate, and implantation of V group element is performed from the backside of the substrate. In some embodiments, implantation of V group element is performed from the front side of the substrate. In some embodiments, implantation of V group element may be performed from both front side and backside of the substrate.

While the embodiments of this disclosure are discussed with respect to nanostructure channel FETs, such as gate all around (GAA) FETs, for example Horizontal Gate All Around (HGAA) FETs or Vertical Gate All Around (VGAA) FETs, implementations of some aspects of the present disclosure may be used in other processes and/or in other devices, such as planar FETs, Fin-FETs, and other suitable devices. A person having ordinary skill in the art will readily understand other modifications that may be made are contemplated within the scope of this disclosure. In cases where gate all around (GAA) transistor structures are adapted, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

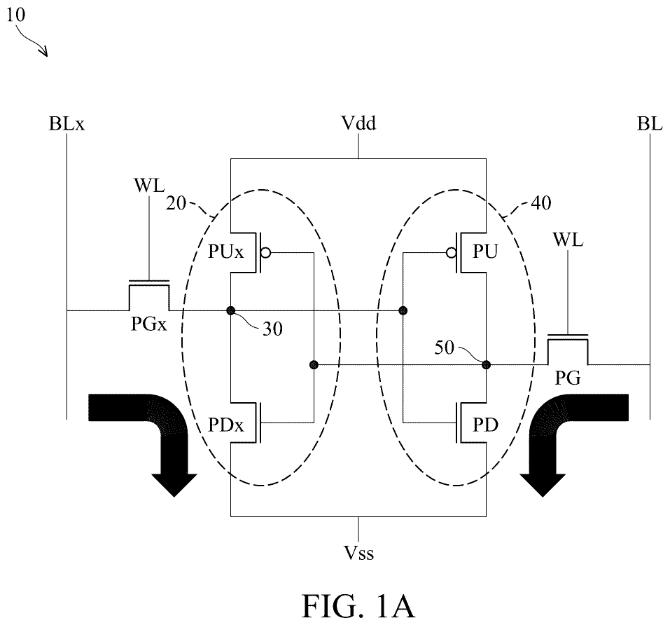

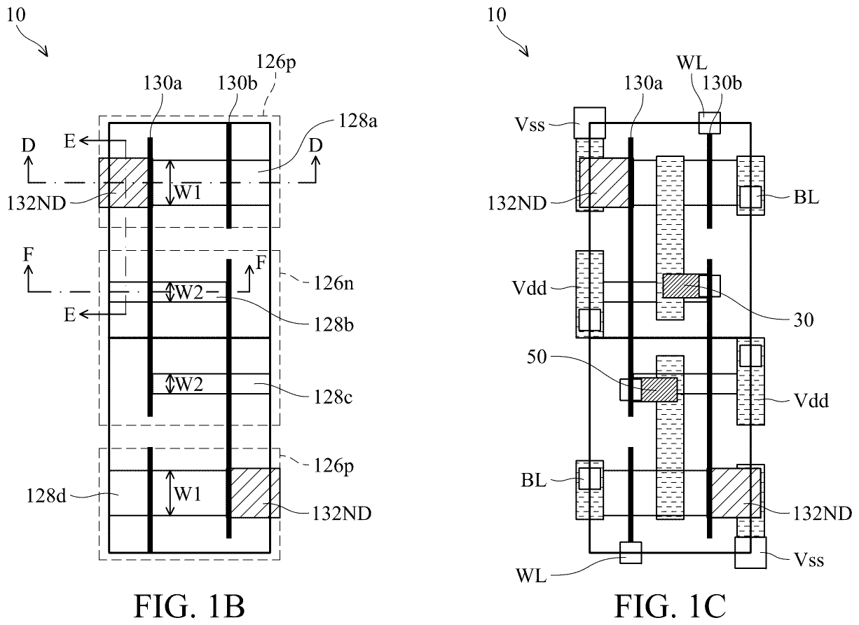

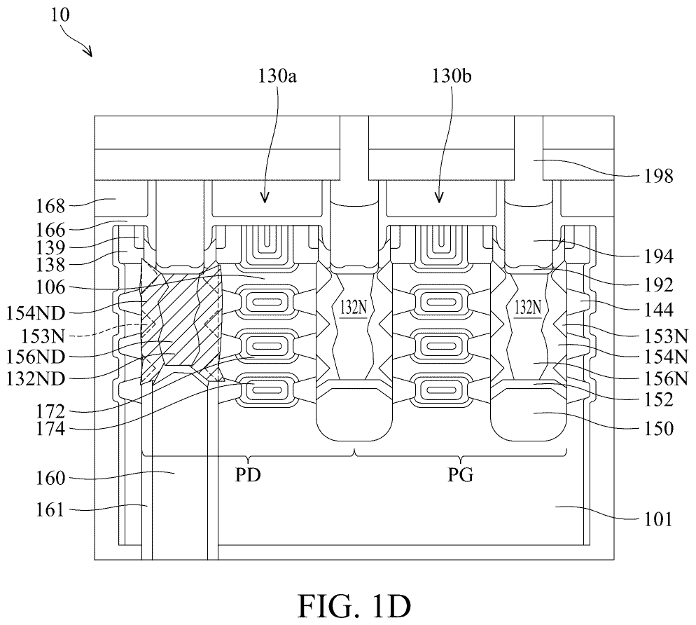

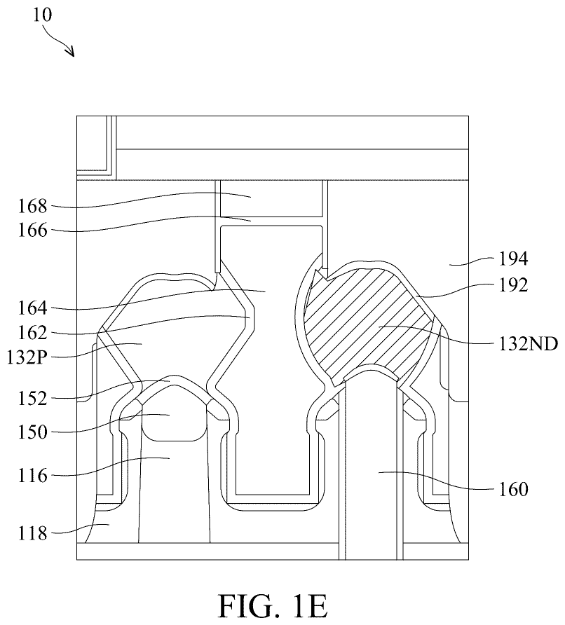

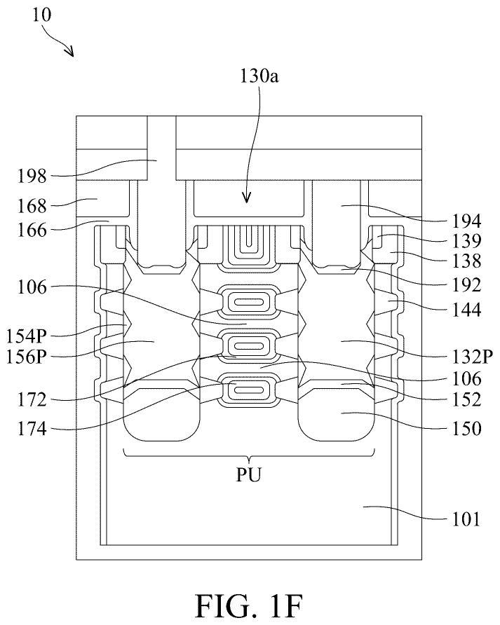

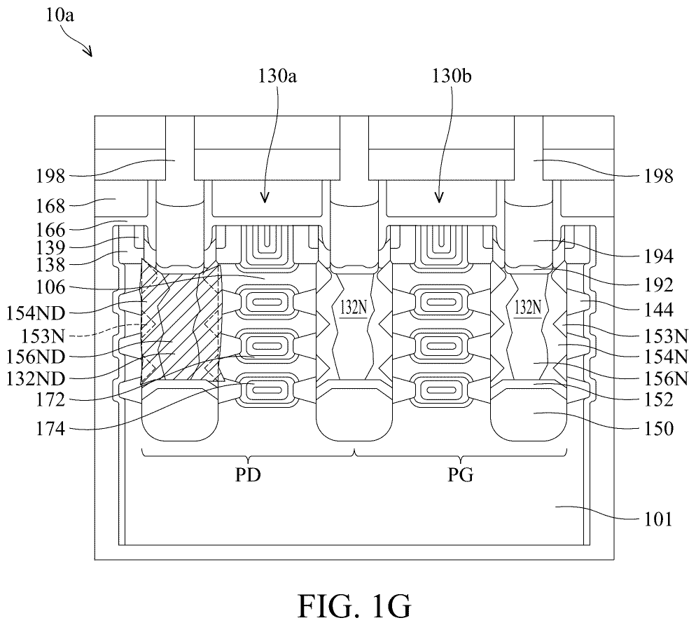

FIG. 1A is a circuit diagram of a six transistor (6T) SRAM cell 10, in accordance with some embodiments. The SRAM cell 10 includes a first inverter 20 formed by a pull-up transistor PUx and a pull-down transistor PDx. The SRAM cell 10 further includes a second inverter 40 formed by a pull-up transistor PU and a pull-down transistor PD. Furthermore, both the first inverter 20 and second inverter 40 are coupled between a voltage bus Vdd and a ground potential Vss. In some embodiments, the pull-up transistors PUx and PU can be p-type metal oxide semiconductor (PMOS) transistors while the pull-down transistors PDx and PD can be n-type metal oxide semiconductor (NMOS) transistors, and the claimed scope of the present disclosure is not limited in this respect.

In FIG. 1A, the first inverter 20 and the second inverter 40 are cross-coupled. That is, the first inverter 20 has an input connected to the output of the second inverter 40. Likewise, the second inverter 40 has an input connected to the output of the first inverter 20. The output of the first inverter 20 is referred to as a storage node 30. Likewise, the output of the second inverter 40 is referred to as a storage node 50. In a normal operating mode, the storage node 30 is in the opposite logic state as the storage node 50. By employing the two cross-coupled inverters, the SRAM cell 10 can hold the data using a latched structure so that the stored data will not be lost without applying a refresh cycle as long as power is supplied through Vdd.

In an SRAM device using the 6T SRAM cells, the cells are arranged in rows and columns. The columns of the SRAM array are formed by a bit line pairs, namely a first bit line BLx and a second bit line BL. The cells of the SRAM device are disposed between the respective bit line pairs. As shown in FIG. 1A, the SRAM cell 10 is placed between the bit line BLx and the bit line BL.

In FIG. 1A, the SRAM cell 10 further includes a first pass-gate transistor PGx connected between the bit line BLx and the storage node 30 of the first inverter 20. The SRAM cell 10 further includes a second pass-gate transistor PG connected between the bit line BL and the storage node 50 of the second inverter 40. The gates of the first pass-gate transistor PGx and the second pass-gate transistor PG are connected to a word line WL, which connects SRAM cells in a row of the SRAM array.

In operation, if the pass-gate transistors PGx and PG are inactive, the SRAM cell 10 will maintain the complementary values at storage nodes 30 and 50 indefinitely as long as power is provided through Vdd. This is so because each inverter of the pair of cross coupled inverters drives the input of the other, thereby maintaining the voltages at the storage nodes. This situation will remain stable until the power is removed from the SRAM, or a write cycle is performed, changing the stored data at the storage nodes.

In the circuit diagram of FIG. 1A, the pull-up transistors PUx, PU are p-type transistors. The pull-down transistors PDx, PD, and the pass-gate transistors PGx, PG are n-type transistors. According to various embodiments, the pull-up transistors PUx, PU, the pull-down transistors PDx, PD, and the pass-gate transistors PGx, PG can be implemented by nanostructure channel FETs.

The structure of the SRAM cell 10 in FIG. 1A is described in the context of the 6T-SRAM. One of ordinary skill in the art, however, should understand that features of the various embodiments described herein may be used for forming other types of devices, such as an 8T-SRAM memory device, or memory devices other than SRAMs. Furthermore, embodiments of the present disclosure may be used as stand-alone memory devices, memory devices integrated with another integrated circuitry, or the like. Accordingly, the embodiments discussed herein are illustrative of ways to make and use the disclosure, and do not limit the scope of the disclosure.

FIG. 1B is a schematic top view of a SRAM cell structure 10 according to embodiments of the present disclosure. FIG. 1C is a schematic top view of the SRAM cell structure 10 showing conductive layers connecting the transistors. Transistors of the SRAM cell structure 10 are formed over a pair of p-wells 126p and a n-well 126n positioned between the pair of p-well 126p on a substrate. Fin structures 128a, 128b, 128c, 128d on the substrate. Gate structures 130a, 130b are formed over the fin structures 128a, 128b, 128c, 128d. Each of the fin structures 128a, 128b, 128c, 128d includes two or more nano-sheet semiconductor channels 128. During fabrication, portions of the fin structures 128a, 128b, 128c, 128d not covered by the gate structures 130a, 130b are etched back, and epitaxial source/drain structures are then formed on both sides of the gate structures 130a, 130b to form the transistors.

The fin structures 128a, 128d are formed over the two p-wells 126p respectively. The fin structures 128a, 128d may have a width w1. The fin structures 128b, 128c are formed over the n-well 126n. The fin structure 128b, 128c may have a width w2. In some embodiments, the width w1 is greater than the width w2. The pull-down transistor PD and pass transistor PG are n-type transistors formed along the fin structure 128a over one p-well 126p, and the pull-down transistor PDx and pass transistor PGx are n-type transistors formed along the fin structure 128d over the other p-well 226p. The pull-up transistors PU and PUx are p-type transistors formed along the fin structures 128b, 128b over the n-well 226n. Gates of the pull-down transistor PD and the pull-up transistor PU are connected. Gates of the pull-down transistor PDx and the pull-up transistor PUx are connected.

In the configuration of FIGS. 1B and 1C, the pulldown transistor PD/PDx and pass gate transistor PG/PGx are formed along the same fin structures 128a/128d, thus, having the substantially same source/drain width (dimension of the source/drain regions along the direction of the gate structures 130a, 130b). As a result, the pulldown transistor PD/PDx and pass gate transistor PG/PGx in traditional SRAM structures have substantially the same saturation currents PD Isat and PG Isat. Therefore, beta, which is defined a ratio of PD Isat/PG Isat, equals to 1 and not adjustable. It has been observed that the value of beta affects the performance of the SRAM transistor.

According to embodiments of the present disclosure, source/drain regions 132ND of the pulldown transistor PD/PDx are implanted with additional n-type dopants, i.e. group V elements, to boost the saturation current PD Isat of the pulldown transistor PD/PDx. By adjusting the concentration of implants to the source/drain region 132ND, beta, i.e. a ratio of PD Isat/PG Isat, may be tuned to improve the SRAM performance. It has been observed that when beta value increases, for example when beta>1.0, statistic noise margin (SNM) for the SRAM increases, thus, reducing the SRAM cell's tolerance to disturbance. Additionally, when beta value increases, inverter switch point may also be lowered. In some embodiments, the beta value may be tuned to be in a range between 1.0 and 4.4. In some embodiments, the beta value is tuned in a range between about 1.0 and about 2.5 to reduce disturbance or improve tolerance to disturbance. Additional implantation to the source/drain region 132ND may also reduce or eliminate any gaps or voids in the source/drain region 132ND. Gaps or voids in the source/drain region may result in higher resistance and weaker SRAM DC performance. Therefore, additional implantation to the source/drain region 132ND according to the present disclosure reduces resistance in the source/drain region 132ND and improves SRAM cell's DC performance.

FIGS. 1D, 1E, and 1F are schematic cross sectional views of the SRAM cell structure 10 along D-D line, E-E line, and F-F line in FIG. 1B according to some embodiments of the present disclosure. The SRAM cell structure 10 includes GAA transistors. FIG. 1D is a schematic cross sectional view along the fin structure 128a showing the source/drain regions and gate structures of the pulldown transistor PD and the pass gate transistor PG. FIG. 1E schematically showing the source/drain regions for the pulldown transistor PD and the pullup transistor PU side by side. FIG. 1F is a schematic cross sectional view along the fin structure 128b showing the source/drain regions and the gate structure of the pullup transistor PD.

In FIGS. 1D, 1E, and 1F, the SRAM cell structure 10 includes GAA transistors. The gate structures 130a, 130b includes two or more semiconductor channel layers 106, a gate dielectric layer 172 disposed around the semiconductor channel layers 106, and a gate electrode layer 174 formed around the gate dielectric layer 172. Source drain regions 132N, 132P (collectively 132) are disposed on opposing sides of the gate structures 130a, 130b forming the transistors. In some embodiments, the source/drain regions 132 are disposed over well portion 116 of the fin structure 128, as shown in FIG. 1E. In some embodiments, a first epitaxy region 150 and an isolation layer 152 are disposed between the well portion 116 and the source/drain regions 132.

As shown in FIG. 1D, the pass gate transistor PG includes source/drain regions 132N disposed on both sides of a gate structure 130b. The source/drain regions 132N includes one or more epitaxial layers having n-type dopants. In some embodiments, each source/drain region 132N includes three layers, a barrier epitaxial layer 153N formed from exposed surfaces of the semiconductor channel layers 106, a transition epitaxial layer 154N formed over the barrier epitaxial layer 153N, and a bulk epitaxial layer 156N formed over the transition epitaxial layer 154N.

In some embodiments, the barrier epitaxial layer 153N include a semiconductor material capable of preventing dopants in the subsequently formed epitaxial layers from diffusing into the semiconductor channel layers 106. In some embodiments, the barrier epitaxial layer 153N includes SiAs. The transition epitaxial layer 154N may be made of one or more layers of Si, SiP, SiC, SiAs, SiSb, and SiCP including n-type dopants, such as phosphorus (P) or arsenic (As). In some embodiments, the transition epitaxial layer 154N includes a SiP layer with n-type dopants in a range from about 1E19 cm⁻³ to about 2E21 cm⁻³. The bulk epitaxial layer 156N may be made of one or more layers of Si, SiP, SiC and SiCP including n-type dopants, such as phosphorus (P) or arsenic (As). In some embodiments, the transition epitaxial layer 154N and the bulk epitaxial layer 156N may include the same semiconductor materials but with different dopant concentrations. The dopant concentration of the bulk epitaxial layer 156N may be substantially greater than the dopant concentration of the transition epitaxial layer 154N. In some embodiments, the dopant concentration of the bulk epitaxial layer 156N may range from about 5E19 cm³ to about 4E21cm⁻³.

As shown in FIG. 1D, the pulldown transistor PD includes the source/drain regions 132N and an enhanced source/drain region 132ND disposed on both sides of a gate structure 130a. The source/drain regions 132N discussed above, and shared with the pass gate transistor PG.

In some embodiments, the enhanced source/drain region 132ND may be fabricated simultaneously with the source/drain regions 132N and then subsequently enhanced with additional dopants or implants. In some embodiments, the enhanced source/drain region 132ND includes three layers, the barrier epitaxial layer 153N formed from exposed surfaces of the semiconductor channel layers 106, an enhanced transition epitaxial layer 154ND formed over the barrier epitaxial layer 153N, and an enhanced bulk epitaxial layer 156ND formed over the enhanced transition epitaxial layer 154ND.

In some embodiments, the dopant concentration in the enhanced transition epitaxial layer 154ND may be greater than the dopant concentration in the transition epitaxial layer 154N in a range between about 1E21 cm⁻³ and about 5E21cm⁻³, for example between about 1E21 cm⁻³ and about 4E21 cm⁻³.

In some embodiments, the dopant concentration in the enhanced bulk epitaxial layer 156ND may be greater than the dopant concentration in the bulk epitaxial layer 156N in a range between about 1E21 cm⁻³ and about 5E21 cm⁻³, for example between about 1E21 cm⁻³ and about 4E21 cm⁻³.

The enhanced transition epitaxial layer 154ND may be made of one or more layers of Si, SiP, SiC, SiAs, SiSb, and SiCP including n-type dopants, such as phosphorus (P) or arsenic (As). In some embodiments, the enhanced transition epitaxial layer 154ND includes a SiP layer with n-type dopants in a range from about 1E21 cm⁻³ to about 5E21 cm⁻³.

The enhanced bulk epitaxial layer 156ND may be made of one or more layers of Si, SiP, SiC and SiCP including n-type dopants, such as phosphorus (P) or arsenic (As). In some embodiments, the enhanced transition epitaxial layer 154N and the enhanced bulk epitaxial layer 156N may include the same semiconductor materials but with different dopant concentrations. The dopant concentration of the enhanced bulk epitaxial layer 156ND may be substantially greater than the dopant concentration of the transition epitaxial layer 154N. In some embodiments, the dopant concentration of the enhanced bulk epitaxial layer 156ND may range from about 1E21 cm⁻³ to about 9E21 cm⁻³.

As shown in FIG. 1F, the pullup transistor PD includes source/drain regions 132P disposed on both sides of a gate structure 130a. The source/drain regions 132P includes one or more epitaxial layers having p-type dopants. In some embodiments, each source/drain region 132P includes two layers, a first source/drain layer 154P formed from the semiconductor channel layers 106 and a bulk epitaxial layer 156P. The first source/drain layer 154P may be made of one or more layers of Si, SiGe, Ge with p-type dopants, such as boron (B). In some embodiments, the dopant concentration of the first source/drain layer 154P may range from about 1×10¹⁹ cm⁻³ to about 2×10²¹ cm⁻³. The bulk epitaxial layer 156P is formed from the first source/drain layer 154P. The bulk epitaxial layer 156P may be made of Si, SiGe, Ge for p-type FETs having p-type dopants, such as boron (B). In some embodiments, the first source/drain layer 154P and the bulk epitaxial layer 156P may include the same semiconductor materials but with different dopant concentrations. The dopant concentration of the bulk epitaxial layer 156P may be substantially greater than the dopant concentration of the first source/drain layer 154P. In some embodiments, the dopant concentration of the bulk epitaxial layer 156P may range from about 5×10¹⁹ cm⁻³ to about 4×10²¹ cm⁻³.

In some embodiments, the pulldown transistor PD is connected to Vss from a backside of the substrate 101. As shown in FIGS. 1D, 1E and 1F, the enhanced source/drain region 132ND may be connected to Vss via a backside contact 160. When connected from the backside, at least a portion of the first epitaxial layer 150 and the isolation layer 152 are removed from the enhanced source/drain region 132ND.

Alternatively, the enhanced source/drain region 132ND may be connected to Vss through the front side source/drain contact 194. FIG. 1G is a schematic cross sectional view of a SRAM cell structure 10a according to embodiments of the present disclosure. The SRAM cell structure 10a is similar to the SRAM cell structure 10 except that the enhanced source/drain region 132ND may be connected to Vss through the front side source/drain contact 194 and contact via 198.

By enhancing the source/drain region of the pulldown transistor PD, the SRAM cell 10, 10a achieved various performance improvement. It has been observed, when enhancing with phosphorus (P) dopants in the concentration range between 1E21 cm⁻³ and 4E21 cm⁻³ to the source/drain region 132ND of the pulldown transistor PD, the beta value (PD/PG Isat) may be improved at be at the range between 1.1 and 1.2; Vmax (voltage overdrive of SRAM cell) increases in a range between about 50 mv and about 100 mv; Vccmin (minimum voltage of SRAM cell Can Pass Read/Write function) reduces in a range between 10 mv and 20 mv; Icell performance increases in a range between about 5% and 10%; and CPF (measurement of SRAM can pass Read/Write function) improves in a range between about 5% and 10%.

The enhancement dopant concentration may be selected according to circuit design and performance target. For example, when enhancing with phosphorus (P) dopants in the concentration range between 1E21 cm⁻³ and 2E21 cm⁻³ to the source/drain region 132ND of the pulldown transistor PD, Vmax increases in a range between about 50 mv and about 70 mv; Vccmin reduces in a range between 10 mv and 13 mv. When enhancing with phosphorus (P) dopants in the concentration range between 2E21 cm⁻³ and 3E21 cm⁻³ to the source/drain region 132ND of the pulldown transistor PD, Vmax increases in a range between about 70 mv and about 85 mv; Vccmin reduces in a range between 13 mv and 16 mv. When enhancing with phosphorus (P) dopants in the concentration range between 3E21 cm⁻³ and 4E21 cm⁻³ to the source/drain region 132ND of the pulldown transistor PD, Vmax increases in a range between about 85 mv and about 100 mv; Vccmin reduces in a range between 16 mv and 20 mv.

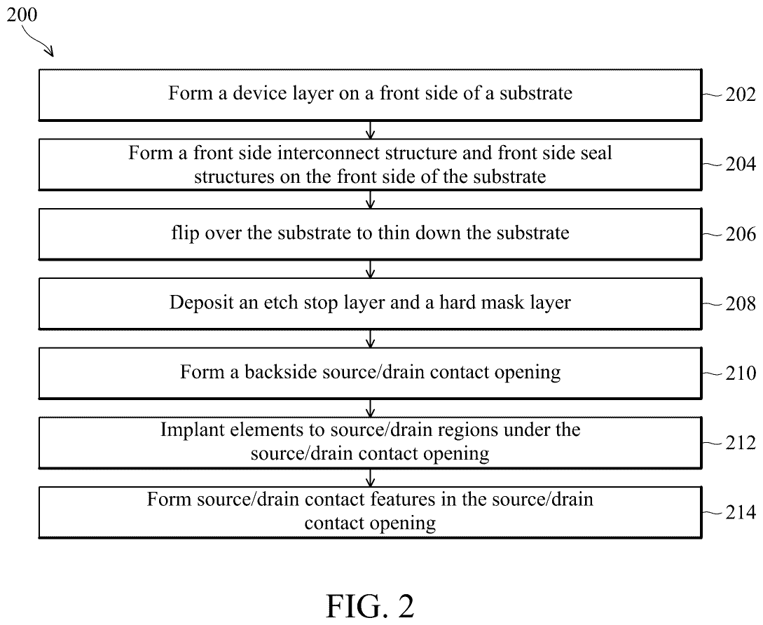

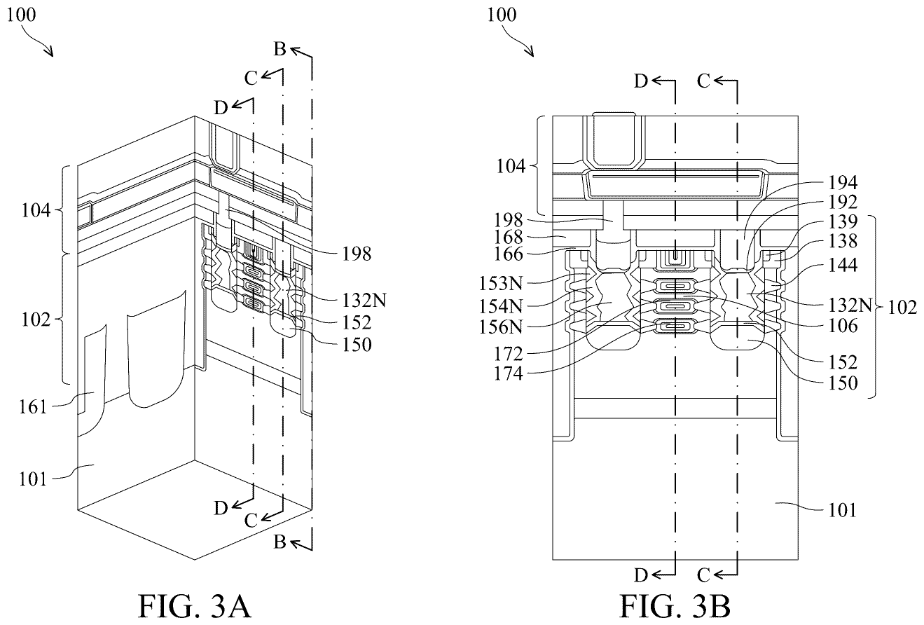

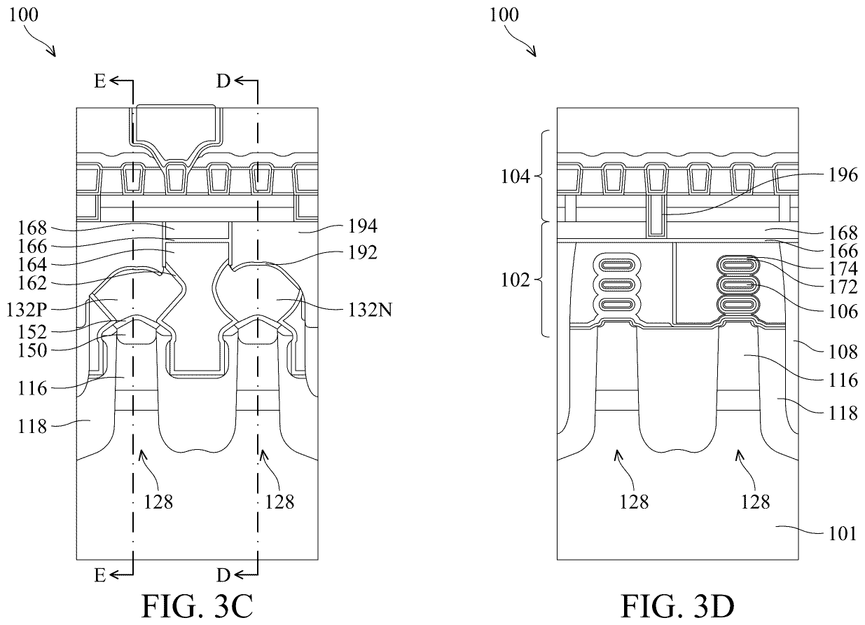

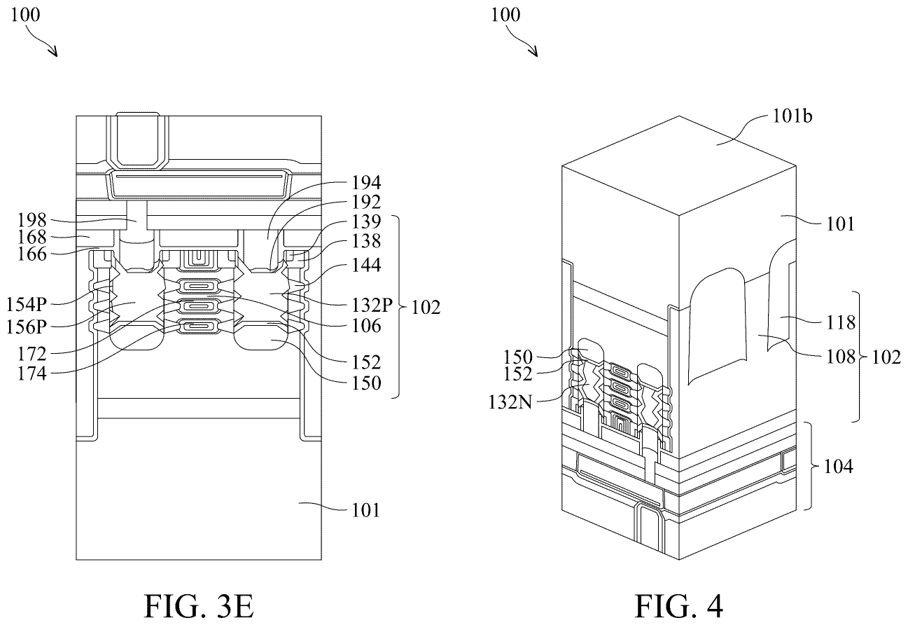

FIG. 2 is a flow chart of a method 200 of forming a semiconductor device according to embodiments of the present disclosure. In some embodiments, the SRAM cell structure 10 may be fabricated using the method 200. FIGS. 3A, 3B, 3C, 3D, 3E, 4, 5A, 5B, 5C, 5D, 6A, 6B, 6C, 6D, 7A, 7B, 7C, 7D, 8A, and 8B schematically illustrate various stages of manufacturing a semiconductor device structure 100 using the method 100 according to embodiments of the present disclosure. It is understood that additional operations can be provided before, during, and after processes shown by the figures, and some of the operations described below can be replaced or eliminated, for additional embodiments of the method. The order of the operations/processes is not limiting and may be interchangeable. The semiconductor device structure 100 being fabricated may include one or more components of the SRAM cell structures 10.

In operation 202 of the method 200, a device layer 102 including transistors rare formed on a front side of the substrate 101, as shown in FIGS. 3A-3E. FIG. 3A is perspective view of a portion of a semiconductor device structure 100 in accordance with some embodiments. FIGS. 3B, 3C, and 3D are schematic cross sectional view of the semiconductor device structure 100 along lines B-B, C-C, and D-D in FIG. 3A. FIG. 3E is schematic cross sectional view of the semiconductor device structure 100 along line E-E in FIG. 3D. As shown in FIGS. 3A-3E, the semiconductor device structure 100 includes transistors with multiple channels formed from a stack of semiconductor layers formed over a front side of a substrate 101.

The substrate 101 may be a semiconductor substrate. The substrate 101 may include a crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP). In some embodiments, the substrate 101 is a silicon-on-insulator (SOI) substrate having an insulating layer (not shown) disposed between two silicon layers for enhancement. In one aspect, the insulating layer is an oxygen-containing layer. In some embodiments, the substrate 101 is a silicon substrate.

The substrate 101 may include various regions that have been doped with impurities (e.g., dopants having p-type or n-type conductivity). Depending on circuit design, the dopants may be, for example phosphorus for an n-type field effect transistors (NFET) and boron for a p-type field effect transistors (PFET).

In some embodiments, a stack of semiconductor layers includes alternating semiconductor layers made of different materials to facilitate formation of nanostructure channels in a multi-gate device, such as nanostructure channel FETs. In some embodiments, the stack of semiconductor layers may include alternating semiconductor channel layers 106 and sacrificial layers (not shown). The semiconductor channel layers 106 and the sacrificial layers are made of semiconductor materials having different etch selectivity and/or oxidation rates. For example, the semiconductor channel layers 106 may be made of Si and the sacrificial layers may be made of SiGe. In some examples, the semiconductor channel layers 106 may be made of SiGe and the sacrificial layers may be made of Si. Alternatively, in some embodiments, either of the semiconductor layers 106 and sacrificial layers may be or include other materials such as Ge, SiC, GaAs, GaP, InP, InAs, InSb, GaAsP, AlInAs, AlGaAs, InGaAs, GaInP, GaInAsP, or any combinations thereof. In some embodiments, the sacrificial layers may be dielectric layers.

The semiconductor stack layers may be formed by any suitable deposition process, such as epitaxy. By way of example, epitaxial growth of the layers of the stack of semiconductor layers may be performed by a molecular beam epitaxy (MBE) process, a metalorganic chemical vapor deposition (MOCVD) process, and/or other suitable epitaxial growth processes.

The semiconductor channel layers 106 or portions thereof may form nanostructure channel(s) of the semiconductor device structure 100 in later fabrication stages. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section. The nanostructure channel(s) of the semiconductor device structure 100 may be surrounded by a gate electrode. The semiconductor device structure 100 may include a nanostructure transistor. The nanostructure transistors may be referred to as nanosheet transistors, nanowire transistors, gate-all-around (GAA) transistors, multi-bridge channel (MBC) transistors, or any transistors having the gate electrode surrounding the channels. The use of the semiconductor channel layers 106 to define a channel or channels of the semiconductor device structure 100 is further discussed below.

Each semiconductor channel layer 106 may have a thickness in a range between about 5 nm and about 30 nm. Each sacrificial layer may have a thickness that is equal, less, or greater than the thickness of the semiconductor channel layer 106. In some embodiments, each sacrificial layer has a thickness in a range between about 2 nm and about 50 nm. Three semiconductor channel layers 106 are shown in FIGS. 3A-3D, which is for illustrative purposes and not intended to be limiting beyond what is specifically recited in the claims. It can be appreciated that any number of semiconductor channel layers 106 can be formed in the stack of semiconductor layers, and the number of layers depending on the predetermined number of channels for the semiconductor device structure 100.

Fin structures 128 are formed from the stack of semiconductor layers. The fin structures 128 may be semiconductor fins. Each fin structure 128 has an upper portion including the semiconductor channel layers 106 and the sacrificial layers 108 and a well portion 116 formed from the substrate 101. The fin structures 128 may be formed by patterning a hard mask layer formed on the stack of semiconductor layers using multi-patterning operations including photo-lithography and etching processes. The etching process can include dry etching, wet etching, reactive ion etching (RIE), and/or other suitable processes. The photo-lithography process may include forming a photoresist layer (not shown) over the hard mask layer, exposing the photoresist layer to a pattern, performing post-exposure bake processes, and developing the photoresist layer to form a masking element including the photoresist layer. In some embodiments, patterning the photoresist layer to form the masking element may be performed using an electron beam (e-beam) lithography process. The etching process forms trenches in unprotected regions through the hard mask layer, through the stack of semiconductor layers, and into the substrate 101, thereby leaving the plurality of extending fin structures 128. The trenches extend along the X direction. The trenches may be etched using a dry etch (e.g., RIE), a wet etch, and/or combination thereof.

After the fin structures 128 are formed, an insulating material is formed on the substrate 101. The insulating material fills the trenches 114 between neighboring fin structures 128 until the fin structures 128 are embedded in the insulating material. Then, a planarization operation, such as a chemical mechanical polishing (CMP) method and/or an etch-back method, is performed such that the top of the fin structures 128 is exposed. The insulating material may be made of silicon oxide, silicon nitride, silicon oxynitride (SiON), SiOCN, SiCN, fluorine-doped silicate glass (FSG), a low-K dielectric material, or any suitable dielectric material. The insulating material may be formed by any suitable method, such as low-pressure chemical vapor deposition (LPCVD), plasma enhanced CVD (PECVD) or flowable CVD (FCVD). The insulating material is recessed to form isolation regions 118. The recess of the insulating material exposes portions of the fin structures 128, such as the stack of semiconductor layers 104. The recess of the insulating material reveals the trenches 114 between the neighboring fin structures 128. The isolation regions 118 may be formed using a suitable process, such as a dry etching process, a wet etching process, or a combination thereof. A top surface of the insulating material may be level with or below a surface of the sacrificial layers in contact with the well portion 116 formed from the substrate 101. In some embodiments, the isolation regions 118 are the shallow trench isolation (STI) regions.

In some embodiments, one or more sacrificial gate structures are formed over the semiconductor device structure 100. The sacrificial gate structures are formed over a portion of the fin structures 128. Each sacrificial gate structure may include a sacrificial gate dielectric layer, a sacrificial gate electrode layer, and a mask layer. The sacrificial gate dielectric layer, the sacrificial gate electrode layer, and the mask layer may be formed by sequentially depositing blanket layers of the sacrificial gate dielectric layer, the sacrificial gate electrode layer, and the mask layer, and then patterning those layers into the sacrificial gate structures.

One or more gate spacers are the formed. In some embodiments, the gate spacers include a first gate spacer 138 and a second gate spacer 139. The first gate spacer 138 is deposited on the exposed surfaces of the semiconductor device structure 100. For example, the first gate spacer 138 is deposited on the fin structures 128, the isolation regions 118, and the sacrificial gate structure. The first gate spacer 138 may be made of a dielectric material such as silicon oxide, silicon nitride, silicon carbide, silicon oxynitride, SiCN, silicon oxycarbide, SiCON, and/or combinations thereof. The first gate spacer 138 may be formed by any suitable process. In some embodiments, the first gate spacer 138 is a conformal layer formed by a conformal process, such as an atomic layer deposition (ALD) process. a second gate spacer 139 is deposited on the first gate spacer 138. The second gate spacer 139 may include any suitable dielectric material, such as SiOₓ, SiON, SiN, SiCON, or SiCO. The second gate spacer 139 may have a thickness ranging from about 0.5 nm to about 5 nm. The second gate spacer 139 may be formed by any suitable process. In some embodiments, the second gate spacer 139 is deposited by CVD, PECVD, or electron cyclotron resonance CVD (ECR-CVD).

The portions of the fin structures 128 not covered by the sacrificial gate structures 130 and the first and second gate spacers 138, 139 are recessed to a level above, at, or below the top surfaces of the isolation regions 118. The recess of the portions of the fin structures 128 can be done by an etch process. The etch process may be a dry etch, such as a RIE, NBE, or the like, or a wet etch, such as using tetramethylammonium hydroxide (TMAH), ammonium hydroxide (NH₄OH), or any suitable etchant. The well portions 116 are exposed on opposite sides of the sacrificial gate structure.

In some embodiments, edge portions of each sacrificial layer of the stack of semiconductor layers are removed horizontally to form inner spacers 144 between the semiconductor channel layers 106. The removal of the edge portions of the sacrificial layers forms cavities. In some embodiments, the portions of the sacrificial layers are removed by a selective wet etch process. In cases where the sacrificial layers are made of SiGe and the semiconductor channel layers 106 are made of silicon, the sacrificial layer can be selectively etched using a wet etchant such as, but not limited to, ammonium hydroxide (NH₄OH), tetramethylammonium hydroxide (TMAH), ethylenediamine pyrocatechol (EDP), or potassium hydroxide (KOH) solutions.

After removing edge portions of each sacrificial layers, a dielectric layer is deposited in the cavities to form the inner spacers 144. The inner spacers 144 may be made of a low-K dielectric material, such as SiON, SiCN, SiOC, SiOCN, or SiN. The inner spacers 144 may be formed by first forming a conformal dielectric layer using a conformal deposition process, such as ALD, followed by an anisotropic etching to remove portions of the conformal dielectric layer other than the inner spacers 144. The inner spacers 144 are protected by the semiconductor channel layers 106 during the anisotropic etching process.

In some embodiments, a first epitaxy region 150 is formed on the exposed well portions 116. In some embodiments, the first epitaxy region 150 includes undoped silicon or undoped SiGe. The first epitaxy region 150 may be first formed on semiconductor surfaces, such as on the exposed well portions 116 and the semiconductor channel layers 106, by epitaxy. A subsequent etch process is performed to remove the portions of the first epitaxy region 150 formed on the semiconductor channel layers 106. The first epitaxy region 150 formed on the exposed well portions 116 may form a concave top surface as the result of the etch process. In some embodiments, the first epitaxy region 150 has a thickness ranging from about 5 nm to about 50 nm along the Z direction.

An isolation layer 152 is then formed on the first epitaxy region 150. The isolation layer 152 may be formed by first forming a dielectric layer on the exposed surfaces of the semiconductor device structure 100, followed by one or more etch processes to remove portions of the dielectric layer other than the isolation layer 152. The isolation layer 152 may include any suitable dielectric material. In some embodiments, the isolation layer 152 includes SiN. The isolation layer 152 may be formed by any suitable process. In some embodiments, the isolation layer 152 is formed by CVD.

Source/drain regions 132P, 132N (collectively source/drain regions 132) are then formed for p-type devices and n-type devices respectively. In some embodiments, each source/drain region 132 may include one or more epitaxial materials. In this disclosure, a source region and a drain region are interchangeably used, and the structures thereof are substantially the same. Furthermore, source/drain region(s) may refer to a source or a drain, individually or collectively, dependent upon the context. In some embodiments, p-type S/D regions and n-type S/D regions may be formed separately using one or more mask layers.

The source/drain regions 132P and 132N include different materials and are formed separately. For example, the source/drain regions 132P for p-type devices may be formed while areas for the source/drain regions 132N are covered by a mask layer and the source/drain regions 132P are covered by a mask layer while the source/drain regions 132N are formed, or vice versa.

The source/drain regions 132N may include two or more sequentially formed epitaxial material layers. In some embodiments, as shown in FIG. 3B, the source/drain regions 132N includes a barrier epitaxial layer 153N formed from exposed surfaces of the semiconductor channel layers 106, a transition epitaxial layer 154N formed over the barrier epitaxial layer 153N, and a bulk epitaxial layer 156N formed over the transition epitaxial layer 154N.

The barrier epitaxial layer 153N is formed from exposed surfaces of the semiconductor channel layers 106. The barrier epitaxial layer 153N may be formed from a semiconductor material capable of preventing dopants in the subsequently formed epitaxial layers from diffusing into the semiconductor channel layers 106. In some embodiments, the barrier epitaxial layer 153N is a compound including a semiconductor material and a V-group element. For example, the barrier epitaxial layer 153N is a compound including silicon and a V-group element, such as SiAs. In some embodiments, the barrier epitaxial layer 153N is SiAs having a ratio of Si:As in a range between about 1.0 and about 3.0.

In some embodiments, the barrier epitaxial layer 153N may include discrete sections around the end portion of the semiconductor channel layers 106. In other embodiments, the barrier epitaxial layer 153N may be a continuous layer. The barrier epitaxial layer 153N may be formed by an epitaxial growth method using CVD, ALD or MBE. In some embodiments, the barrier epitaxial layer 153N is selectively formed on semiconductor materials, such as the semiconductor channel layers 106, and is not formed on dielectric materials, such as the isolation layer 152 and the inner spacers 144. In some embodiments, the first source/drain layer 154 includes facets, which may correspond to crystalline planes of the material used for the semiconductor channel layers 106.

The transition epitaxial layer 154N may be made of one or more layers of Si, SiP, SiC, SiAs, SiSb, and SiCP including n-type dopants, such as phosphorus (P) or arsenic (As). In some embodiments, the transition epitaxial layer 154N includes a SiP layer with n-type dopants in a range from about 1×10¹⁹ cm⁻³ to about 2×10²¹ cm⁻³. The transition epitaxial layer 154N may be formed by an epitaxial growth method using CVD, ALD or MBE. In some embodiments, the first source/drain layer 154 is a continuous layer over the barrier epitaxial layer 153N and the inner spacers 144. The transition epitaxial layer 154N does not contact the semiconductor channel layers 106. The barrier epitaxial layer 153N is disposed between the transition epitaxial layer 154N and the semiconductor channel layers 106. In some embodiments, the transition epitaxial layer 154N is selectively formed on semiconductor materials, such as the barrier epitaxial layer 153N, and is not formed on dielectric materials, such as the isolation layer 152 and the inner spacers 144.

The bulk epitaxial layer 156N is formed from the transition epitaxial layer 154N. The bulk epitaxial layer 156N may be formed by an epitaxial growth method using CVD, ALD or MBE. The bulk epitaxial layer 156N may be made of one or more layers of Si, SiP, SiC and SiCP including n-type dopants, such as phosphorus (P) or arsenic (As). In some embodiments, the transition epitaxial layer 154N and the bulk epitaxial layer 156N may include the same semiconductor materials but with different dopant concentrations. The dopant concentration of the bulk epitaxial layer 156N may be substantially greater than the dopant concentration of the transition epitaxial layer 154N. In some embodiments, the dopant concentration of the bulk epitaxial layer 156N may range from about 5×10¹⁹ cm⁻³ to about 4×10²¹ cm⁻³. The bulk epitaxial layer 156N may be epitaxially grown from the transition epitaxial layer 154N. The quality of the bulk epitaxial layer 156N may be improved due to the facets of the transition epitaxial layer 154N.

The barrier epitaxial layer 153N, the transition epitaxial layer 154N, and the bulk epitaxial layer 156N together may be the source/drain (S/D) region 132N. In some embodiments, the first source/drain layer 154 and the bulk epitaxial layer 156 are crystalline semiconductor materials.

As shown in FIG. 3E, the source/drain regions 132P may include a first source/drain layer 154P and a bulk epitaxial layer 156P. The first source/drain layer 154P may be made of one or more layers of Si, SiGe, Ge with p-type dopants, such as boron (B). In some embodiments, the dopant concentration of the first source/drain layer 154P may range from about 1×10¹⁹ cm⁻³ to about 2×10²¹ cm⁻³. The first source/drain layer 154P may be formed by an epitaxial growth method using CVD, ALD or MBE. In some embodiments, the first source/drain layer 154P is selectively formed on semiconductor materials, such as the semiconductor channel layers 106, and is not formed on dielectric materials, such as the isolation layer 152 and the inner spacers 144.

The bulk epitaxial layer 156P is formed from the first source/drain layer 154P. The bulk epitaxial layer 156P may be formed by an epitaxial growth method using CVD, ALD or MBE. The bulk epitaxial layer 156P may be made of Si, SiGe, Ge for p-type FETs having p-type dopants, such as boron (B). In some embodiments, the first source/drain layer 154P and the bulk epitaxial layer 156P may include the same semiconductor materials but with different dopant concentrations. The dopant concentration of the bulk epitaxial layer 156P may be substantially greater than the dopant concentration of the first source/drain layer 154P. In some embodiments, the dopant concentration of the bulk epitaxial layer 156P may range from about 5×10¹⁹ cm⁻³ to about 4×10²¹ cm⁻³. The bulk epitaxial layer 156P may be epitaxially grown from the first source/drain layer 154P. The first source/drain layer 154P and the bulk epitaxial layer 156P together may be the source/drain (S/D) region 132P.

A contact etch stop layer (CESL) 162 is conformally formed on the exposed surfaces of the semiconductor device structure 100. The CESL 162 covers the second gate spacer 139, the isolation regions 118, and the bulk epitaxial layer 156 of the source/drain regions 132. The CESL 162 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be formed by CVD, PECVD, ALD, or any suitable deposition technique. In some embodiments, the CESL 162 is a single layer. In some embodiments, the CESL 162 includes two or more layers. Next, an interlayer dielectric (ILD) layer 164 is formed on the CESL 162. The materials for the ILD layer 164 may include compounds including Si, O, C, and/or H, such as silicon oxide, SiCOH, or SiOC. Organic materials, such as polymers, may also be used for the ILD layer 164. The ILD layer 164 may be deposited by a PECVD process or other suitable deposition technique. In some embodiments, after formation of the ILD layer 164, the semiconductor device structure 100 may be subject to a thermal process to anneal the ILD layer 164.

A replacement gate process is then performed to remove the sacrificial gate structure and form the gate structures 130a, 130b. The gate structure 130a, 130b may include a gate dielectric layer 170 and a gate electrode layer 172. The gate dielectric layer 170 is formed to surround the exposed portions of the semiconductor channel layers 106, and the gate electrode layer 172 is formed on the gate dielectric layer 170. In some embodiments, an interfacial layer (IL) (not shown) is formed between the gate dielectric layer 170 and the exposed surfaces of the semiconductor channel layers 106, and one or more work function layers (not shown) are formed between the gate dielectric layer 170 and the gate electrode layer 172. In some embodiments, the gate dielectric layer 170 includes one or more layers of a dielectric material, such as silicon oxide, silicon nitride, or high-K dielectric material, other suitable dielectric material, and/or combinations thereof. Examples of high-K dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-K dielectric materials, and/or combinations thereof. The gate dielectric layer 170 may be formed by CVD, ALD or any suitable deposition technique. The work function layer may include polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, or other suitable materials. The gate electrode layer 172 may include one or more layers of conductive material, such as platinum (Pt), palladium (Pd), tantalum (Ta), ytterbium (Yb), aluminum (Al), silver (Ag), titanium (Ti), ruthenium (Ru), molybdenum (Mo), chromium (Cr), tungsten (W), copper (Cu), or similar material, and/or any combinations thereof. The gate electrode layer 172 may be formed by CVD, ALD, electro-plating, or other suitable deposition technique. The gate electrode layer 172 may also be deposited over the upper surface of the ILD layer 164. The gate dielectric layer 170 and the gate electrode layer 172 formed over the ILD layer 164 are then removed by using, for example, CMP, until the top surface of the ILD layer 164 is exposed. It is understood that the semiconductor device structure 100 may undergo further processes, such as cut metal gate (CMG) process and/or continuous poly on diffusion edge (CPODE) process. The CMG process separates the gate electrode layer 172 into multiple segments that can be individually controlled. The CPODE process forms isolation structures 108 between devices.

An etch stop layer 166 and a second ILD layer 168 are formed over the ILD layer 164 and the gate electrode layer 172. The etch stop layer 166 may include the same material as the CESL 162 and may be formed by the same process as the CESL 162. The second ILD layer 168 may include the same material as the ILD layer 164 and may be formed by the same process as the ILD layer 164. Openings are formed in the second ILD layer 168, the etch stop layer 166, the ILD layer 164, and the CESL 162 to expose the bulk epitaxial layer 156. In some embodiments, portions of the ILD layer 164 and the CESL 162 located over the bulk epitaxial layer 156 may be removed. The openings may be formed by an etch process, such as a dry etch process, a wet etch process, or a combination thereof. A patterned mask may be formed over the second ILD layer 168, and the pattern of the patterned mask is transferred to the second ILD layer 168, the etch stop layer 166, the ILD layer 164, and the CESL 162.

Silicide layers 192 are formed on the exposed portions of the source/drain regions 132. The silicide layer 192 may be formed by any suitable process. In some embodiments, a metal layer is first formed on the semiconductor device structure 100. The metal layer may include Ti, Ni, Ru, Co, W, or other suitable metal. In some embodiments, the metal layer is a multi-layer structure. The multi-layer structure may include a metal layer and a metal nitride or metal oxide layer. The metal layer may be deposited by any suitable process, such as ALD, CVD, or PVD. After the metal layer deposition, an annealing process is performed to react the bulk epitaxial layer 156 with the metal layer, thereby forming the silicide layers 192. The silicide layer 192 may include any suitable material, such as NiSi, TiSi, CoSi, RuSi, or WSi.

Source/drain contacts 194 are deposited in the openings. The source/drain contact 194 may be electrically conductive and may include a material having one or more of Ru, Mo, Co, Ni. W, Ti, Ta, Cu, Al, TiN or TaN. The source/drain contact 194 may be formed by any suitable method, such as electro-chemical plating (ECP), or PVD.

In operation 204 of the method 200, a front side interconnect structure 104 are formed over the device layer 102. The front side interconnect structure 104 may include multiple layers of dielectric materials with conductive lines and vias embedded in the dielectric layers. The conductive lines and vias provide electrical connection to the source/drain contacts 192 and the gate electrode layers 174 to supply signal and/or power to the transistors in the device layer 102. As shown in FIGS. 3A-3D, conductive features 196, 198 are formed to in the front side interconnect structure 104 to connect with the gate electrode layer 174 and the source/drain contacts 192.

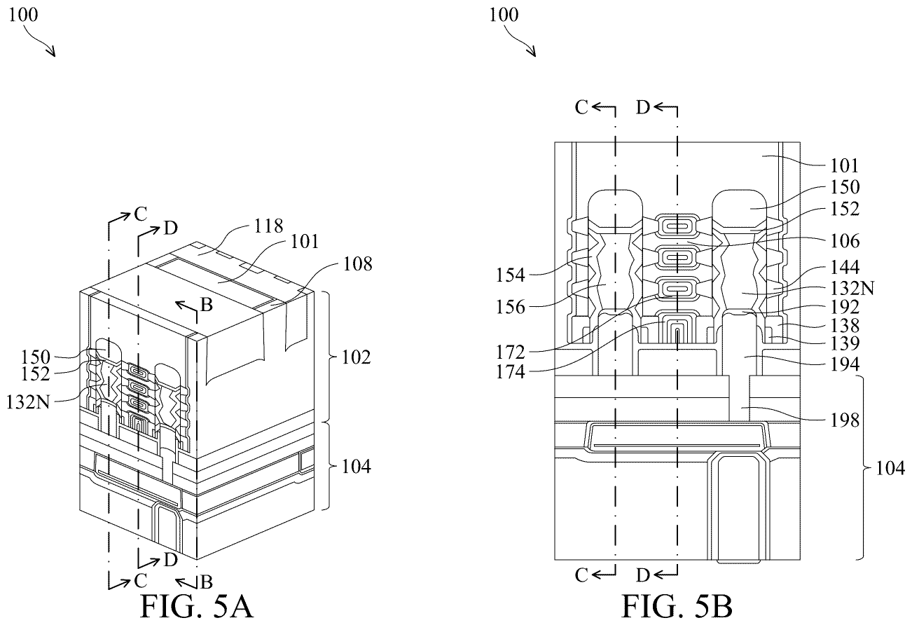

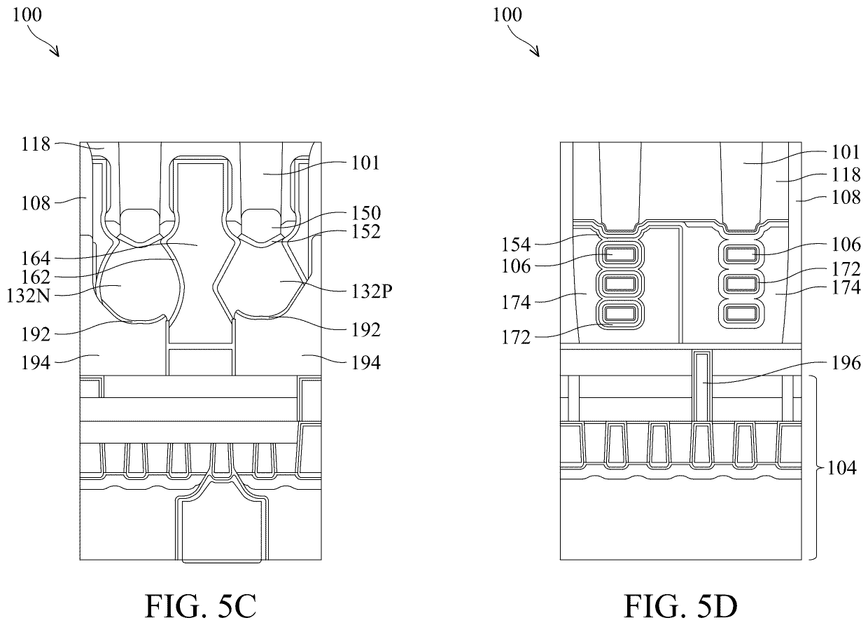

In operation 206 of the method 200, the semiconductor device structure 100 is flipped over and the substrate 101 is thinned down for backside processing, as shown in FIG. 4 and FIGS. 5A-5D. FIG. 4 and FIG. 5A are schematic perspective views of the semiconductor device structure 100. FIGS. 5B, 5C, and 5D are schematic cross sectional views of the semiconductor device structure 100 along lines B-B, C-C, and D-D in FIG. 5A. After forming the front side interconnect structure 104, the semiconductor device structure 100 is flipped over and a backside thinning process is performed. In some embodiments, a carrier wafer (not shown) may be bonded to a front side of the semiconductor device structure 100, and the semiconductor device structure 100 is flipped over so that a backside 101b of the substrate 101, is facing up for backside processing, as shown in FIG. 4. The backside 101b of the substrate 101 may be thinned using a planarization or grinding operation, such as a CMP process. After the substrate 101 is thinned, a backside surface 100b of the semiconductor substrate structure 100 includes the substrate 101, the isolation regions 118, and the isolation structures 108, as shown in FIG. 5A.

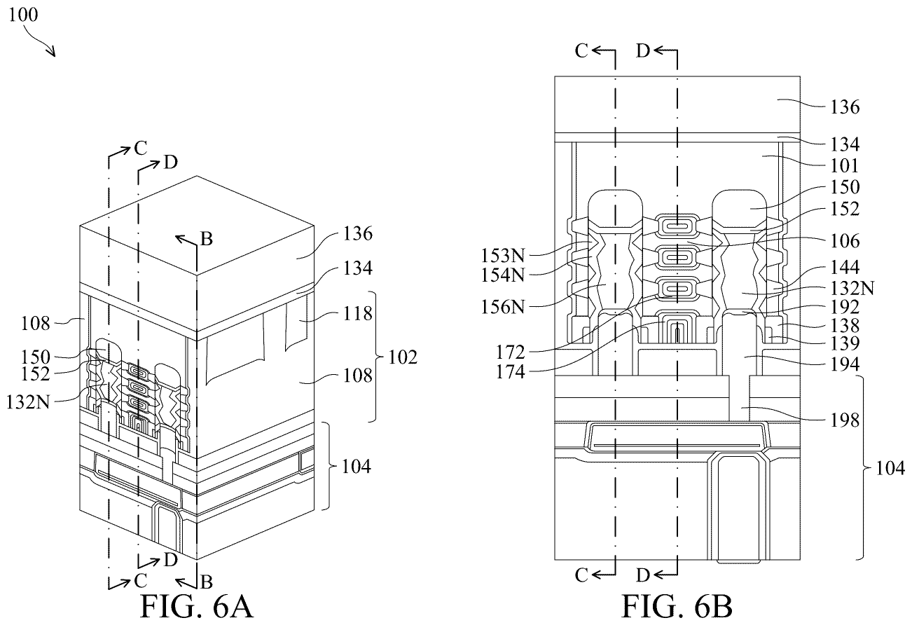

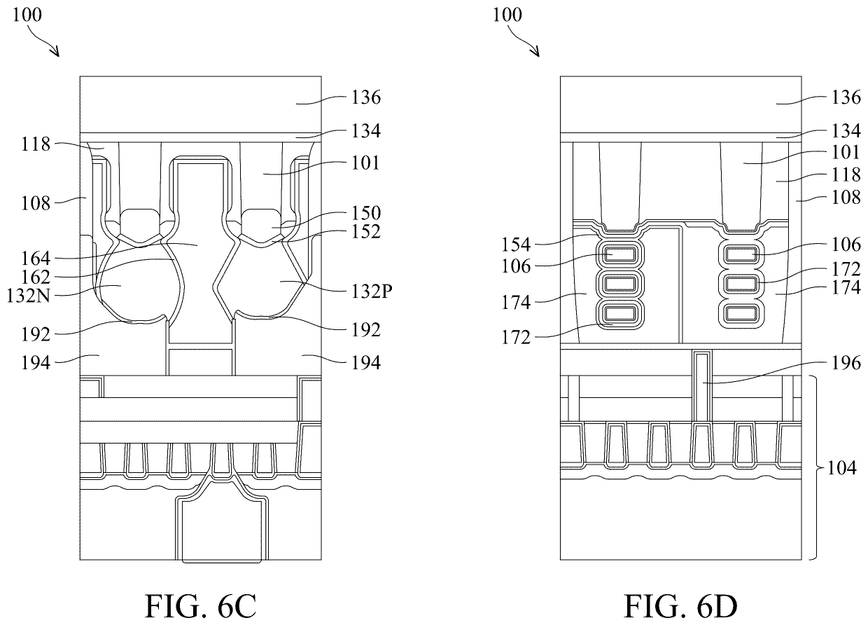

In operation 208 of the method 200, an etch stop layer 134 and a hard mask layer 136 are deposited over the backside surface 100b of the semiconductor device structure 100, as shown in FIGS. 6A-6D. FIG. 6A is a schematic perspective view of the semiconductor device structure 100. FIGS. 6B, 6C, and 6D are schematic cross sectional views of the semiconductor device structure 100 along lines B-B, C-C, and D-D in FIG. 6A.

The etch stop layer 134 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be formed by CVD, PECVD, ALD, or any suitable deposition technique. In some embodiments, the etch stop layer 134 includes a silicon nitride layer having a thickness in a range between about 5 nm and about 13 nm.

The hard mask layer 136 may include compounds including Si, O, C, and/or H, such as silicon oxide, SiCOH, or SiOC. In some embodiments, the hard mask layer 136 may be a silicon oxide layer having a thickness in a range between about 20 nm and about 60 nm. The hard mask layer 136 may be deposited by a PECVD process or other suitable deposition technique.

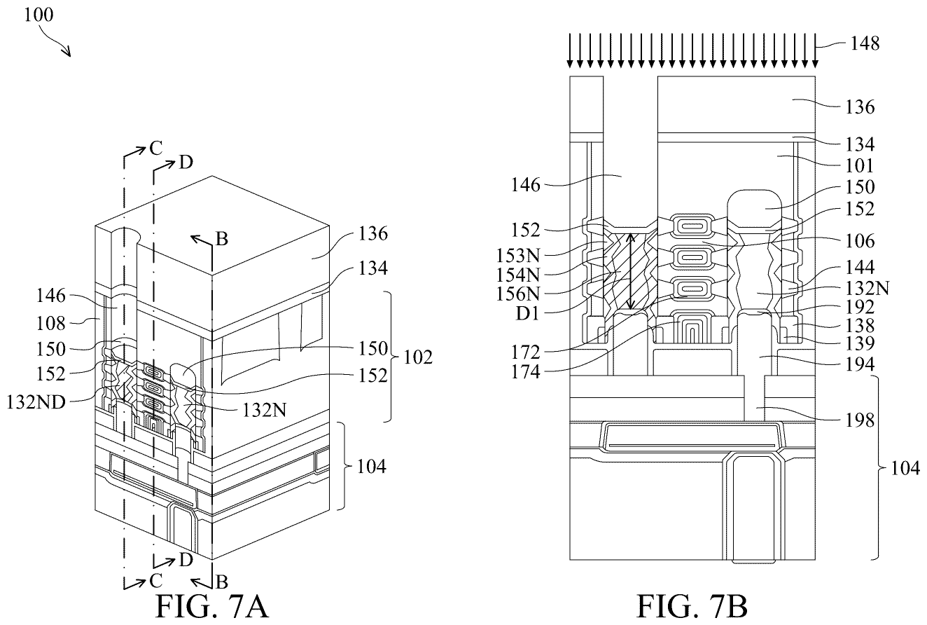

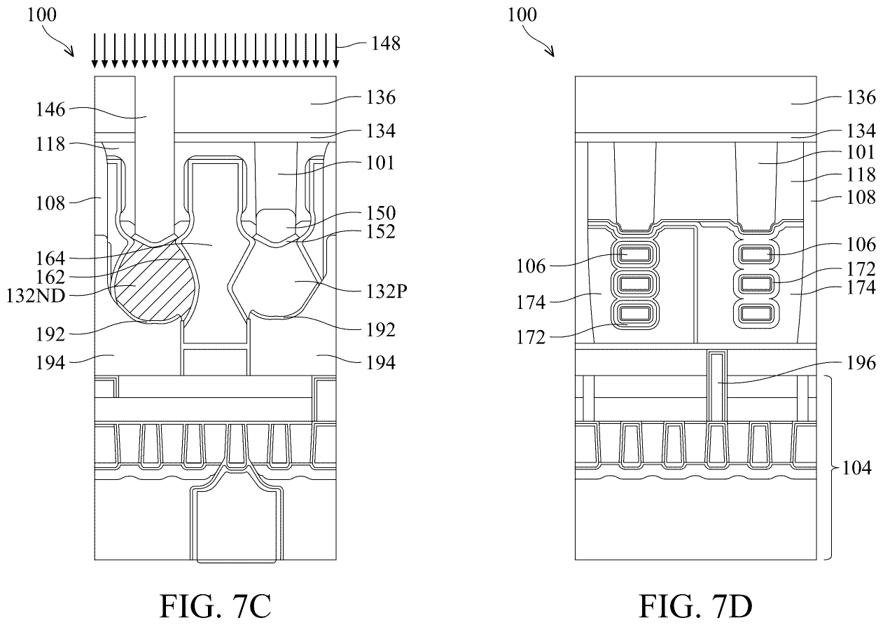

In operation 210 of the method 200, backside source/drain contact openings 146 are formed, as shown in FIGS. 7A-7D. FIG. 7A is a schematic perspective view of the semiconductor device structure 100. FIGS. 7B, 7C, and 7D are schematic cross sectional views of the semiconductor device structure 100 along lines B-B, C-C, and D-D in FIG. 7A.

In some embodiments, the openings 146 are aligned with the source/drain regions 132N to be connected from the backside, for example, to be connected to a low voltage power source Vss. In the example of the SRAM structure, the opening 146 may be aligned with the drain region of the pulldown transistors PD/PDx.

In some embodiments, the openings 146 are aligned with the source/drain regions 132N without exposing the source/drain regions 132N, as shown in FIGS. 7B and 7C. The openings 146 are formed through the hard mask layer 136, the etch stop layer 134, the substrate 101, the first epitaxy layer 150 to expose the isolation layer 152 above the source/drain region 132N.

The openings 146 may be formed by an etch process, such as a dry etch process, a wet etch process, or a combination thereof. A pattern of openings may be formed in the hard mask layer 136 over the substrate 101, and the pattern of the patterned hard mask layer 134 is transferred to the substrate 101 and first epitaxy region 150.

In operation 212 of the method 200, an implantation process is performed to implant into the source/drain regions 132N under the openings 146, as shown in FIGS. 7A-7D. In some embodiments, dopants 148 reach the source/drain regions 132N under at the bottom of the contact openings 146. The hard mask layer 136 protects source/drain regions outside the contact openings 146. The dopants 148 enter the source/drain regions 132N under the contact openings 146. In one aspect, the dopants 148 increase dopant concentration in the source/drain regions 132N resulting increased saturation current. In another aspect, the dopants 148 may improve crystalline structure of the source/drain regions 132N by filling or reducing sizes of voids or vacancies in the source/drain regions 132N.

In some embodiments, the implantation process implants one or more dopants corresponding to the existing dopants in the source/drain regions being doped. For example, n-type dopants, such as P and As, are implanted into the n-type source/drain regions 132N. In some embodiments, the implantation process implant one or more V-group elements to the n-type source/drain regions 132N.

In the embodiments shown in FIG. 7A-7D, the dopants 148 enter the bulk epitaxial layer 156N and the transition epitaxial layer 154N in the source/drain regions 132N. In some embodiment, the dopants 148 do not enter the barrier layer 153N because of the elements and crystalline structure of the barrier layer 153N. Additionally, the barrier layer 153N may further prevent diffusion of the dopants from the transition epitaxial layer 154N and the bulk epitaxial layer 156N to the semiconductor channel layers 106.

The implantation process may be performed at an energy level and a duration to achieve target dopant concentrations and to reach target dopant depth ranges. In some embodiments, the implantation process is performed in an implantation energy ranging from about 3 k eV to about 4 k eV.

In some embodiments, a doped depth d1 of a doped region is within a range between about 30 nm and about 40 nm, as shown in FIG. 7B. In some embodiments, the doped depth d1 covers at least two semiconductor channel layers 106. In some embodiments, the doped depth d1 covers all the semiconductor channel layers 106, e.g., from a bottommost semiconductor channel layer 106 to a topmost semiconductor layer 106. The doped depth d1 and the number of covered semiconductor channel layers 106 may fine-tuned according to circuit design.

The implantation process converts the source/drain regions being doped to enhanced source/drain regions 132ND. In some embodiments, the dopants are phosphorous. In some embodiments, the dopant concentration added to the source/drain regions 132ND in operation 212 is in a range between about 1E21 cm⁻³ to about 5E21 cm⁻³, for example in a range between about 1E21 cm⁻³ and about 4E21 cm⁻³. That is to say, compared to the source/drain regions 132N, which is not doped during operation 212, the doped source/drain regions 132 ND have a higher concentration on n-type dopants. As discussed above, the source/drain regions 132N may include n-type dopants at a concentration range from about 5E19 cm⁻³ to about 4E21 cm⁻³. Accordingly, the enhanced source/drain regions 132ND may have n-type dopants in a concentration ranging between about 1E21 cm⁻³ to about 8E21 cm⁻³.

In some embodiments, the difference between the dopant concentrations between the doped source/drain regions 132 ND and the source/drain regions 132N may be selected to tune the beta value (PD/PG Isat).

In some embodiments, the dopants have a uniform distribution along the doped depth d1. In other embodiments, the dopants have a concentration gradient along the doped depth d1. For example, the dopants have a higher concentration near the isolation layer 152 or the level of the bottom semiconductor channel layer 106 and a lower concentration near the source/drain contact 194 or the level of the topmost semiconductor channel layer 106.

In some embodiments, the dopants are evenly distributed in the bulk epitaxial layer 156N and the transition epitaxial layer 154N. In other embodiments, the dopants have a concentration gradient from the bulk epitaxial layer 156N to the transition epitaxial layer 154N.

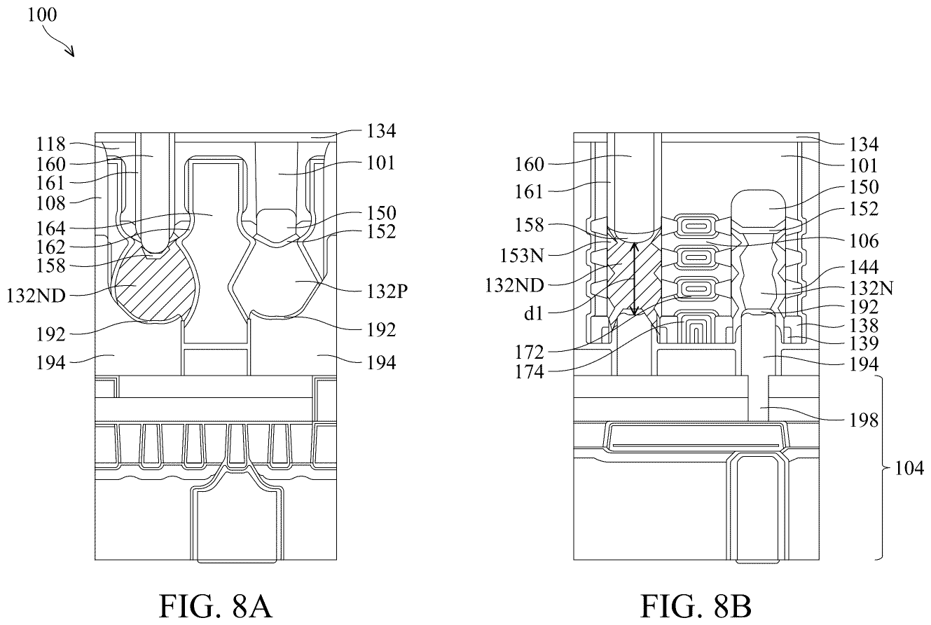

In operation 214 of the method 200, backside source/drain contacts 160 are formed in the contact openings 146, as shown in FIGS. 8A and 8B. In some embodiments, after the implantation process, the isolation region 152 is removed from the bottom of the contact openings 146 to expose the enhanced source/drain regions 132ND.

In some embodiments, a silicide layer 158 is first formed on the exposed surfaces of the enhanced source/drain regions 132ND. In some embodiments, a liner 161 is formed in the contact openings 146, e.g. on the substrate 101, the isolation layer 152, the first epitaxial layer 150 if remaining on the sidewall of the contact openings 146, and the isolation region 118. The liner 161 may include any suitable material. In some embodiments, the liner 161 is a nitride layer, such as a silicon nitride layer. In some embodiments, the liner 161 includes the same material as the etch stop layer 134. The liner 161 may be formed by first forming a dielectric layer on the exposed surfaces of the semiconductor device structure 100, followed by an anisotropic etch process to remove portions of the dielectric layer formed on horizontal surfaces of the semiconductor device structure 100. For example, portions of the dielectric layer formed on the enhanced source/drain regions 132ND are removed by the anisotropic etch process.

The backside source/drain contacts 160 are then formed to electrically connected to the enhanced source/drain regions 132ND. The backside source/drain contacts 160 may be electrically conductive and may include a material having one or more of Ru, Mo, Co, Ni. W, Ti, Ta, Cu, Al, TiN or TaN, and the backside source/drain contacts 160 may be formed by any suitable method, such as electro-chemical plating (ECP), or PVD. After forming the backside source/drain contacts 160, a planarization operation, such as a CMP process, may be performed to remove the excessive conductive materials and the hard mask layer 136.

After the planarization operation, a backside interconnect structure may be formed to connect the backside source/drain contact 160. In some embodiments, the semiconductor device structure 100 includes SRAM cells and the backside source/drain contact 160 is a Vss node and may be connected to low voltage bus Vss via the backside interconnect structure.

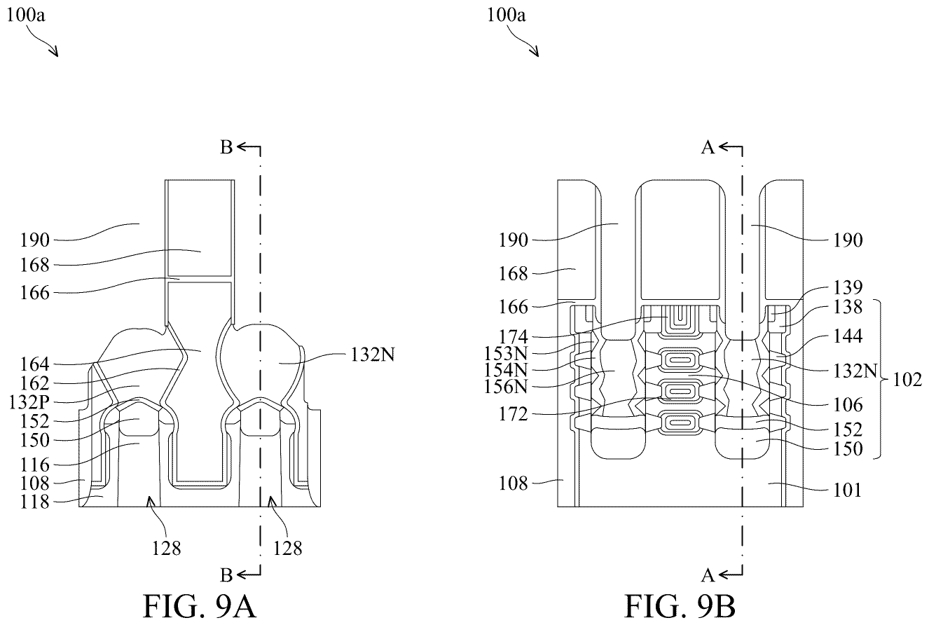

FIGS. 9A-9B, 10A-10B, and 11A-11B schematically illustrate various stage of manufacturing a semiconductor device structure 100a according to embodiments of the present disclosure. In some embodiments, when the semiconductor device structure 100a includes SRAM cells 10, FIGS. 9A, 10A, 11A are cross sectional view along the E-E line in FIG. 1B and FIGS. 9B, 10B, and 11B are cross sectional views of the pulldown transistor PD along the D-D line in FIG. 1B. The semiconductor device structure 100a may be fabricated in a similar manor to the semiconductor device structure 100 described above except that an enhancement implantation is performed to some source/drain regions prior to formation of the front side source/drain contacts 194.

FIGS. 9A-9B are schematic cross sectional views of the semiconductor device structure 100a prior to forming the front side source/drain contacts 194. Front side source/drain contact openings 190 are formed in the second ILD layer 168, the etch stop layer 166, the ILD layer 164, and the CESL 162 to expose the bulk epitaxial layer 156 in the source/drain regions 132. In some embodiments, portions of the ILD layer 164 and the CESL 162 located over the bulk epitaxial layer 156 may be removed.

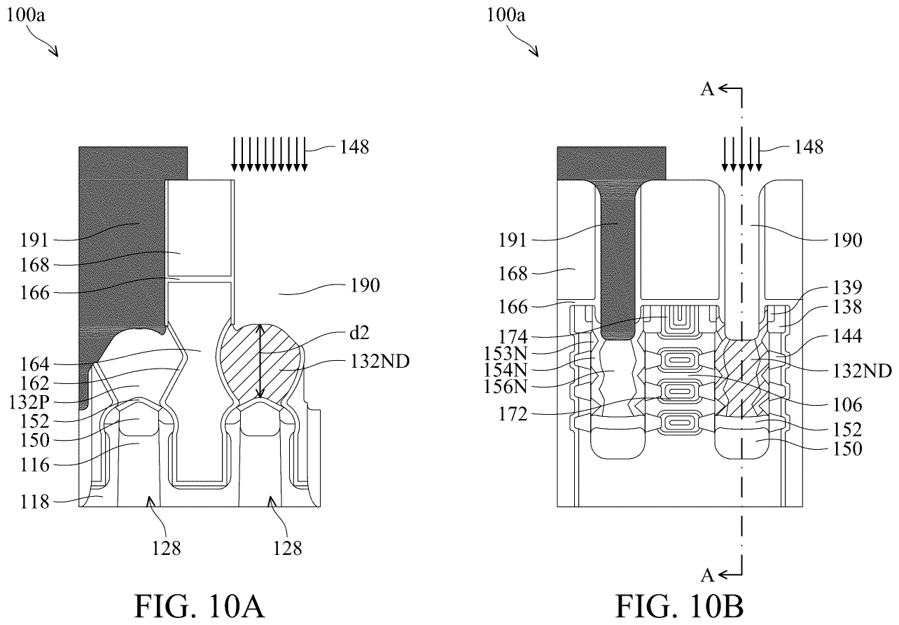

In some embodiments, a patterned mask layer 191 may be formed over the semiconductor device structure 100a to expose a portion of the source/drain regions 132 for a front side enhancement implantation process, as shown in FIGS. 10A-10B. In some embodiments, the patterned mask layer 191 may be a patterned photoresist layer. In some embodiments, the patterned mask layer 191 exposes a portion of the n-type source/drain regions 132N. For example, the drain region of the pulldown transistor PD/PDx, i.e. the n-type source/drain region 132N of the pulldown transistor PD/PDx to be connected to the Vss note, are exposed by the patterned mask layer 191.

An implantation process is then performed to include additional dopants to exposed source/drain regions 132N resulting in enhanced source/drain regions 132ND. The implantation process may be similar to the implantation process described in operation 212. In some embodiments, dopants 148 reach the source/drain regions 132N under at the bottom of the exposed contact openings 190. The patterned mask layer 191 protects source/drain regions 132N, 132P underneath. The dopants 148 enter the source/drain regions 132N exposed by the contact openings 191. In one aspect, the dopants 148 increase dopant concentration in the source/drain regions 132N resulting increased saturation current. In another aspect, the dopants 148 may improve crystalline structure of the source/drain regions 132N by filling or reducing sizes of voids or vacancies in the source/drain regions 132N.

In some embodiments, the implantation process implants one or more dopants corresponding to the existing dopants in the source/drain regions being doped. For example, n-type dopants, such as P and As, are implanted into the n-type source/drain regions 132N. In some embodiments, the implantation process implant one or more V-group elements to the n-type source/drain regions 132N.

In some embodiments, the dopants 148 enter the bulk epitaxial layer 156N and the transition epitaxial layer 154N in the source/drain regions 132N. In some embodiment, the dopants 148 do not enter the barrier layer 153N because of the elements and crystalline structure of the barrier layer 153N. Additionally, the barrier layer 153N may further prevent diffusion of the dopants from the transition epitaxial layer 154N and the bulk epitaxial layer 156N to the semiconductor channel layers 106.

The implantation process may be performed at an energy level and a duration to achieve target dopant concentrations and to reach target dopant depth ranges. In some embodiments, the implantation process is performed in an implantation energy ranging from about 3 k eV to about 4 k eV. In some embodiments, a doped depth d2 of a doped region is within a range between about 30 nm and about 40 nm. In some embodiments, the doped depth d2 covers at least two semiconductor channel layers 106. In some embodiments, the doped depth d2 covers all the semiconductor channel layers 106, e.g., from a topmost semiconductor channel layer 106 to the bottom most semiconductor layer 106. The doped depth d2 and the number of covered semiconductor channel layers 106 may fine-tuned according to circuit design. The implantation process converts the source/drain regions being doped to enhanced source/drain regions 132ND. In some embodiments, the dopants are phosphorous. In some embodiments, the dopant concentration added to the source/drain regions 132ND in operation 212 is in a range between about 1E21 cm⁻³ to about 5E21 cm⁻³, for example in a range between about 1E21 cm⁻³ and about 4E21 cm⁻³.

In some embodiments, the front side enhancement implantation, shown in Figurers 10A-10B, may be used in place of the backside enhancement implantation, shown in FIGS. 7A-7D and in operation 212. In other embodiments, the front side enhancement implantation, shown in FIGS. 10A-10B, may be used in combination with the backside enhancement implantation, shown in FIGS. 7A-7D.

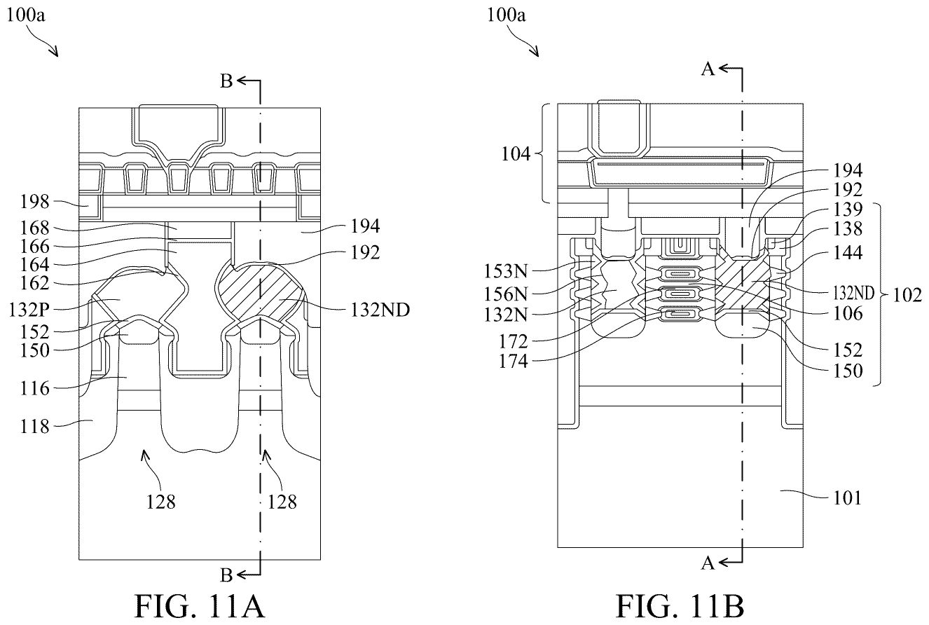

As shown in FIGS. 11A-11B, after the front side enhancement implantation, the patterned mask layer 191 is removed to expose all the source/drain regions 132. The silicide layers 192 are formed on the exposed surfaces of the source/drain regions 132. The silicide layer 192 may be formed by any suitable process. The source/drain contacts 194 are deposited in the contact openings 191. The front side interconnect structure 104 are then formed over the semiconductor device structure 100a.

In some embodiments, backside processing, for example operations 206, 208, 210, 212, and 214 in the method 200, is further performed to the semiconductor device structure 100a, resulting in a semiconductor substrate device with backside Vss connection, similar to the semiconductor device structure shown in FIGS. 8A-8B.

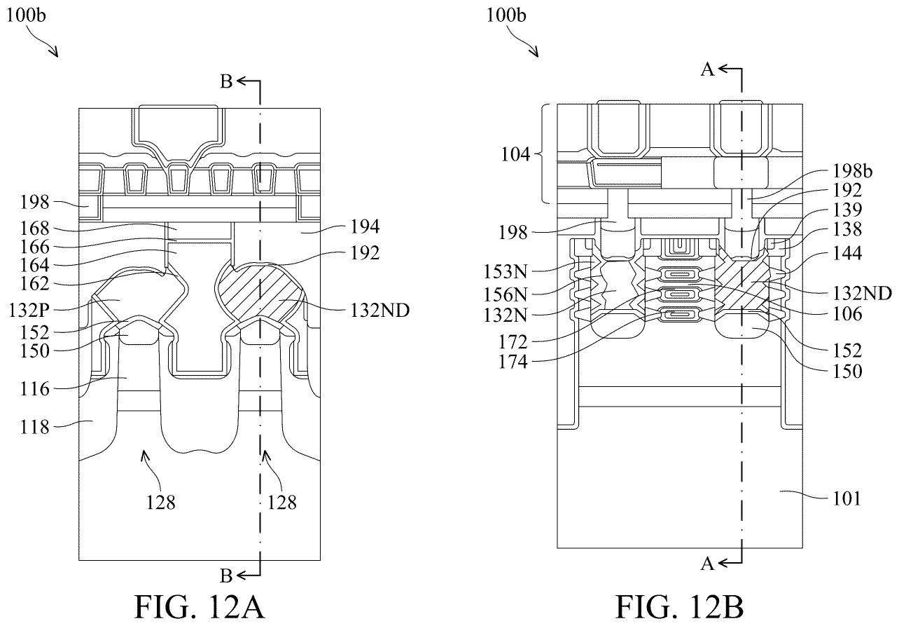

Alternatively, the semiconductor device structure 100a may be completed without the backside processing. For example, after the front side enhancement implantation shown in FIGS. 10A-10B, the enhanced source/drain regions 132ND are connected to the Vss node through the front side interconnect structure. FIGS. 12A-12B schematically illustrate a semiconductor device structure 100b according to embodiments of the present disclosure. FIG. 12A is a cross sectional view along the E-E line in FIG. 1B and FIG. 12B is a cross sectional view of the pulldown transistor PD along the D-D line in FIG. 1B.

The semiconductor device structure 100b is similar to the semiconductor device structure 100 except that the enhanced source/drain regions 132ND are connected to Vss node through a front side via 198b instead of the backside contact 160.

Even though GAA devices are described above, embodiments of the present disclosure may be used in other structures, for example FinFET devices, such as SRAM cells with FinFET transistors.

Embodiments of the present disclosure provide a semiconductor device structure and methods of forming the same. In some embodiments, an implantation process is performed to implant a dopant into a S/D region to improve device performance, for example, to tune SRAM beta ratio, to improve SRAM Vmax and Vccmin, and to boost SRAM Icell performance and reduce current crowding.

Some embodiments of the present provide a method comprising: forming a transistor on a front side of a substrate, wherein the transistor comprises: a first source/drain region; a second source/drain region; a channel region adjacent to the first and second source/drain region; and a gate structure formed on the channel region, wherein the first and second source/drain regions include dopants of a first type with a first concentration; forming a mask layer over the transistor, wherein the mask layer includes an opening, the first source/drain region is covered by the mask layer, and the second source/drain region is aligned with the opening; performing an implantation process to add dopants of the first type; and forming a source/drain contact in the opening to connect with the second source/drain region.

Some embodiments of the present disclosure provide a semiconductor structure comprising: a first source/drain region; a second source/drain region; a first channel region connected to the first and second source/drain region; and a first gate structure disposed on the first channel region, wherein the first source/drain region includes dopants of a first type with a first concentration, the second source/drain region includes dopants of the first type at a second concentration, wherein the second concentration is greater than the first concentration in a range between about 1E21 cm⁻³ and about 4E21 cm⁻³.

Some embodiments of the present disclosure provide a memory cell comprising a first transistor comprising a first source/drain region; a second source/drain region; and a first channel region connected to the first and second source/drain region; and a second transistor, comprising: the first source/drain region; a third source/drain region; and a second channel region connected to the first and third source/drain region, wherein the first source/drain region and the third source/drain region includes n-type dopants at a first concentration, the second source/drain region includes n-type dopants at a second concentration, wherein the second concentration is greater than the first concentration

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method, comprising:
forming a transistor on a front side of a substrate, wherein the transistor comprises:
a first source/drain region;
a second source/drain region;
a channel region adjacent to the first and second source/drain region; and
a gate structure formed on the channel region, wherein the first and second source/drain regions include dopants of a first type with a first concentration;
forming a mask layer over the transistor, wherein the mask layer includes an opening, the first source/drain region is covered by the mask layer, and the second source/drain region is aligned with the opening;
performing an implantation process to add dopants of the first type; and
forming a source/drain contact in the opening to connect with the second source/drain region.

2. The method of claim 1, wherein the first type is N-type.

3. The method of claim 1, wherein after the implantation process, the second source/drain region has a second concentration of the dopants, and the second concentration is greater than the first concentration in a range between about 1E21 cm⁻³ and about 4E21 cm⁻³.

4. The method of claim 1, wherein the transistor comprises:
forming the first and second source/drain regions simultaneously, comprising:
forming a first barrier epitaxial layer and a second barrier epitaxial layer on opposing ends of the channel region;
forming a first transition epitaxial layer on the first barrier epitaxial layer and a second transition epitaxial layer on the second barrier epitaxial layer; and
forming a first bulk epitaxial layer on the first transition epitaxial layer and a second bulk epitaxial layer on the second transition epitaxial layer.

5. The method of claim 4, wherein the first and second barrier layers comprise SiAs.

6. The method of claim 4, wherein performing an implantation process comprises implanting the second transition epitaxial layer and the second bulk epitaxial layer.

7. The method of claim 1, wherein the mask layer is formed over a backside of the substrate, and the source/drain contact is a backside contact.

8. The method of claim 1, wherein the mask layer is formed over the front side of the substrate.

9. A semiconductor structure, comprising:
a first source/drain region;
a second source/drain region;
a first channel region connected to the first and second source/drain region; and
a first gate structure disposed on the first channel region, wherein the first source/drain region includes dopants of a first type with a first concentration, the second source/drain region includes dopants of the first type at a second concentration, wherein the second concentration is greater than the first concentration in a range between about 1E21 cm⁻³ and about 4E21 cm⁻³.

10. The semiconductor structure of claim 9, wherein the first source/drain region comprises:
a first barrier epitaxial layer disposed on a first end of the first channel region;
a first transition epitaxial layer disposed on the first barrier epitaxial layer; and
a first bulk epitaxial layer disposed on the first transition epitaxial layer;
the second source/drain region comprises:
a second barrier epitaxial layer on a second end of the first channel region;
a second transition epitaxial layer disposed on the second barrier epitaxial layer; and
a second bulk epitaxial layer on the second transition epitaxial layer.

11. The semiconductor structure of claim 10, wherein the first type is N-type, and first and second barrier epitaxial layer comprise SiAs.

12. The semiconductor structure of claim 11, wherein the second transition epitaxial layer and the second bulk epitaxial layer have higher dopant concentration than the first transition epitaxial layer and the first bulk epitaxial layer.

13. The semiconductor structure of claim 9, further comprising:
a second channel region, wherein the first source/drain region is connected to a first end of the second channel region; and
a third source/drain region connected to a second end of the second channel region, wherein the third source/drain region includes dopants of the first type at the first concentration.

14. The semiconductor structure of claim 9, wherein the first channel region comprises two or more vertically stacked semiconductor channel layers.

15. The semiconductor structure of claim 9, further comprising:
a first front side source/drain contact disposed on the first source/drain region;
a second front side source/drain contact disposed on the second source/drain region; and
a backside source/drain contact disposed on the second source/drain region.

16. A memory cell, comprising:
a first transistor, comprising:
a first source/drain region;
a second source/drain region; and
a first channel region connected to the first and second source/drain region; and
a second transistor, comprising:
the first source/drain region;
a third source/drain region; and
a second channel region connected to the first and third source/drain region,
wherein the first source/drain region and the third source/drain region includes n-type dopants at a first concentration, the second source/drain region includes n-type dopants at a second concentration, wherein the second concentration is greater than the first concentration.

17. The memory cell of claim 16, wherein the second concentration is greater than the first concentration in a range between about 1E21 cm⁻³ and about 4E21 cm⁻³.

18. The memory cell of claim 16, wherein the first channel region comprises two or more vertically stacked semiconductor channel layers.

19. The memory cell of claim 18, wherein each of the first, second, and third source/drain regions comprises:
a barrier epitaxial layer disposed on end portions of semiconductor channel layers;
a transition epitaxial layer disposed on the barrier epitaxial layer; and
a first bulk epitaxial layer disposed on the transition epitaxial layer.

20. The memory cell of claim 16, wherein the second source/drain region is connected to a low voltage power source Vss.
